(19) United States
(12) Patent Application Publication
(10) Pub. No.: US 2019/0157561 A1
(43) Pub. Date: May 23, 2019

(54) VAPOR DEPOSITION MASK AND MANUFACTURING METHOD OF VAPOR DEPOSITION MASK

(71) Applicant: Japan Display Inc., Tokyo (JP)

(72) Inventor: Yuki MATSUURA, Tokyo (JP)

(21) Appl. No.: 16/191,613

(22) Filed: Nov. 15, 2018

(30) Foreign Application Priority Data
Nov. 21, 2017 (JP) 2017-223456

(51) Int. Cl. H01L 51/00; C23C 14/04; C23C 14/24; H01L 51/56; B23K 26/38

(52) U.S. Cl. CPC H01L 51/0011; C23C 14/042; B23K 26/38; C23C 14/24; H01L 51/56; H01L 51/001

(57) ABSTRACT

A manufacturing method of a vapor deposition mask including forming a first film on a substrate, forming a mask member on the first film, forming a first pattern by etching the first film using the mask member, forming a vapor deposition mask member on a side surface of the first pattern and a side surface of the mask member, and removing the first film and the mask member.

### CROSS REFERENCE TO RELATED APPLICATIONS

This application is based upon and claims the benefit of priority from the prior Japanese Patent Application No. 2017-223456, filed on Nov. 21, 2017, the entire contents of which are incorporated herein by reference.

### FIELD

One embodiment of the present invention is related to a vapor deposition mask, a manufacturing method of a vapor deposition mask, or a manufacturing method of a display device which utilizes a vapor deposition mask.

### BACKGROUND

A liquid crystal display device and an organic EL (Electroluminescence) display device can be given as one example of a flat panel type display device. These display devices are structures in which thin films containing various materials such as insulators, semiconductors and conductors are stacked above a substrate. The function of a display device is realized by appropriately patterning and connecting these thin films.

Methods for forming a thin film are roughly classified into a vapor phase method, a liquid phase method and a solid phase method. The gas phase method is classified into a physical gas phase method and a chemical gas phase method. A vapor deposition method is known as a typical example of a physical vapor phase method. The most convenient method among the vapor deposition methods is a vacuum vapor deposition method. In the vacuum vapor deposition method, a material is heated under a high vacuum which sublimates or vaporizes the material and a vapor of the material is produced (these are generally referred to as vaporization herein). In a region for depositing this material (referred to as a vapor deposition region herein), the vaporized material solidifies and is deposited to so that a thin film of the material is obtained. A vacuum deposition is performed using a mask (deposition mask) in order to form a thin film selectively on the deposition region and in order to ensure that no material is deposited on others region (referred to as non-deposition region herein) (see Japanese Laid Open Patent Publications No. 2009-87840 and No. 2013-209710).

In Japanese Laid Open Patent Publications No. 2009-87840 and No. 2013-209710, the sidewall of an opening of a deposition mask is tapered in order to form a thin film having a uniform thickness in the deposition region. In order to form this taper shape, it is necessary to perform wet etching using a resist mask. As a result, it is difficult to form an opening with a fine pitch. There is a method which is known of adjusting the taper shape of the resist mask to be used as a mold of the vapor deposition mask as a method of making the opening side wall of the vapor deposition mask into a taper shape. However, since there is a large variation in the manufacturing process of the vapor deposition mask, the opening size of the vapor deposition mask varies.

### SUMMARY

A manufacturing method of a vapor deposition mask in one embodiment according to the present invention includes forming a first film on a substrate, forming a mask member on the first film, forming a first pattern by etching the first film using the mask member, forming a vapor deposition mask member on a side surface of the first pattern and a side surface of the mask member, and removing the first film and the mask member.

A vapor deposition mask in an embodiment according to the present invention includes a first surface, a second surface on an opposite side to the first surface, and an opening passing through from the first surface to the second surface, wherein a side wall of the opening is separated into a first side wall, a second side wall and a third side wall from the first surface toward the second surface, and an angle of the second side wall with respect to a horizontal direction is smaller than an angle of the first side wall with respect to a horizontal direction, and an angle of the third side wall with respect to a horizontal direction is larger than an angle of the first side wall with respect to a horizontal direction, on the condition that the first surface is placed on a horizontal surface.

A vapor deposition mask in an embodiment according to the present invention includes a first surface, a second surface on an opposite side to the first surface, and an opening passing through from the first surface to the second surface, wherein a side wall of the opening includes a first side wall and a second side wall, the first side wall is a side wall between a first opening end on the first surface side of the opening and a first point, and forms a first angle with respect to a horizontal direction, and the second side wall is a side wall between a second point further to the outer side than the first point in a planar view and a second opening end on the second surface side of the opening, and forms a second angle with respect to a horizontal direction, the second angle being larger than the first angle.

A manufacturing method of a display device in an embodiment according to the present invention includes forming a plurality of pixel electrode above a substrate, arranging the substrate above an evaporation source filled with a material so that it is positioned between the pixel electrode and the evaporation source, arranging a vapor deposition mask between the evaporation source and the substrate, and vaporizing the material to form a film including the material above the pixel electrode. The vapor deposition mask includes a first surface, a second surface on an opposite side to the first surface; and an opening passing through from the first surface to the second surface. A side wall of the opening is separated into a first side wall, a second side wall and a third side wall from the first surface toward the second surface. An angle of the second side wall with respect to a horizontal direction is smaller than an angle of the first side wall with respect to a horizontal direction, and an angle of the third side wall with respect to a horizontal direction is larger than an angle of the first side wall with respect to a horizontal direction, on the condition that the first surface is placed on a horizontal surface.

A manufacturing method of a display device in an embodiment according to the present invention includes forming a plurality of pixel electrodes above a substrate, arranging the substrate above an evaporation source filled with a material so that it is positioned between the pixel electrode and the evaporation source, arranging a vapor deposition mask between the evaporation source and the substrate, and vaporizing the material to form a film including the material above the pixel electrode. The vapor deposition mask includes a first surface, a second surface on an opposite side to the first surface; and an opening passing through from the first surface to the second surface. A side wall of the opening includes a first side wall and a second side wall. A side wall of the opening includes a first side wall and a second side wall. The first side wall is a side wall between a first opening end on the first surface side of the opening and a first point, and forms a first angle with respect to a horizontal direction. The second side wall is a side wall between a second point further to the outer side than the first point in a planar view and a second opening end on the second surface side of the opening, and forms a second angle with respect to a horizontal direction, the second angle being larger than the first angle.

### BRIEF DESCRIPTION OF DRAWINGS

FIG. 1 is a top surface diagram of a vapor deposition device related to one embodiment of the present invention;

FIG. 2 is a side surface diagram of a vapor deposition device related to one embodiment of the present invention;

FIG. 3 is a cross-sectional diagram of an evaporation source related to one embodiment of the present invention;

FIG. 4 is a top surface diagram of a vapor deposition mask related to one embodiment of the present invention;

FIG. 5 is an expanded top surface diagram of a vapor deposition mask related to one embodiment of the present invention;

FIG. 6 is a cross-sectional diagram of a vapor deposition mask related to one embodiment of the present invention;

FIG. 7 is a cross-sectional diagram showing a manufacturing method of a vapor deposition mask related to one embodiment of the present invention;

FIG. 8 is a cross-sectional diagram showing a manufacturing method of a vapor deposition mask related to one embodiment of the present invention;

FIG. 9 is a cross-sectional diagram showing a manufacturing method of a vapor deposition mask related to one embodiment of the present invention;

FIG. 10 is a cross-sectional diagram showing a manufacturing method of a vapor deposition mask related to one embodiment of the present invention;

FIG. 11 is a cross-sectional diagram showing a manufacturing method of a vapor deposition mask related to one embodiment of the present invention;

FIG. 12 is a cross-sectional diagram showing a manufacturing method of a vapor deposition mask related to one embodiment of the present invention;

FIG. 13 is a cross-sectional diagram of a vapor deposition mask related to one embodiment of the present invention;

FIG. 14 is a cross-sectional diagram showing a manufacturing method of a vapor deposition mask related to one embodiment of the present invention;

FIG. 15 is a cross-sectional diagram showing a manufacturing method of a vapor deposition mask related to one embodiment of the present invention;

FIG. 16 is a top surface diagram of a display device related to one embodiment of the present invention;

FIG. 17 is a cross-sectional diagram of a display device related to one embodiment of the present invention;

FIG. 18A is a cross-sectional diagram showing a manufacturing method of a display device related to one embodiment of the present invention;

FIG. 18B is a cross-sectional diagram showing a manufacturing method of a display device related to one embodiment of the present invention;

FIG. 19 is a cross-sectional diagram showing a manufacturing method of a display device related to one embodiment of the present invention;

FIG. 20A is a cross-sectional diagram showing a manufacturing method of a display device related to one embodiment of the present invention;

FIG. 20B is a cross-sectional diagram showing a manufacturing method of a display device related to one embodiment of the present invention;

FIG. 21A is a cross-sectional diagram showing a manufacturing method of a display device related to one embodiment of the present invention; and

FIG. 21B is a cross-sectional diagram showing a manufacturing method of a display device related to one embodiment of the present invention.

### DESCRIPTION OF EMBODIMENTS

Each embodiment of the present invention is explained below while referring to the drawings. However, the present invention can be implemented in various modes without departing from the gist of the invention and should not to be interpreted as being limited to the description of the embodiments exemplified below.

Although the drawings may be schematically represented in terms of width, thickness, shape, and the like of each part as compared with their actual mode in order to make explanation clearer, it is only an example and an interpretation of the present invention is not limited. In the present specification and each drawing, the same reference numerals are provided to the same elements as those described above with reference to preceding figures and a detailed explanation may be omitted accordingly.

In the present invention, when a single film is etched or irradiated with light to form a plurality of films, these films may have different functions and roles. However, the plurality of films is derived from films formed in the same layer by the same process and have the same layer structure and the same material. Therefore, these films are defined as existing in the same layer.

In the present specification and the scope of the patent claims, when expressing a mode in which another structure is arranged above a certain structure, in the case where it is simply described as [above ] or [on], unless otherwise noted, a case where another structure is arranged directly above (or on) a certain structure as if in contact with that structure, and a case where another structure is arranged via another structure above (or on) a certain structure, are both included.

One embodiment of the present invention aims to provide a vapor deposition mask with high accuracy and a manufacturing method thereof which is suitable for forming a thin film with a uniform thickness in a vapor deposition region by a vapor deposition method. Alternatively, one aim of the present invention is to provide a formation method of a thin film using the vapor deposition mask and a manufacturing method of a display device which utilizes this formation method.

### First Embodiment

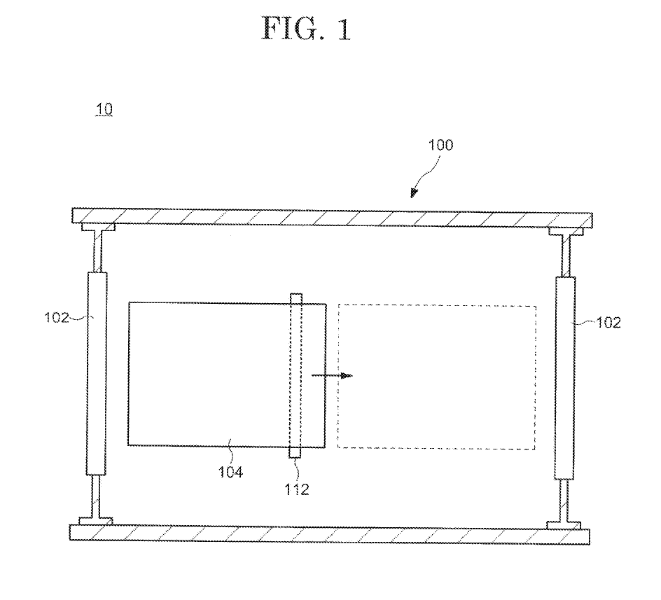

A vapor deposition mask, a vapor deposition device which uses the vapor deposition mask, and a method of forming a thin film according to one embodiment of the present invention are explained using FIG. 1 to FIG. 12.

[Structure of Vapor Deposition Device 10]

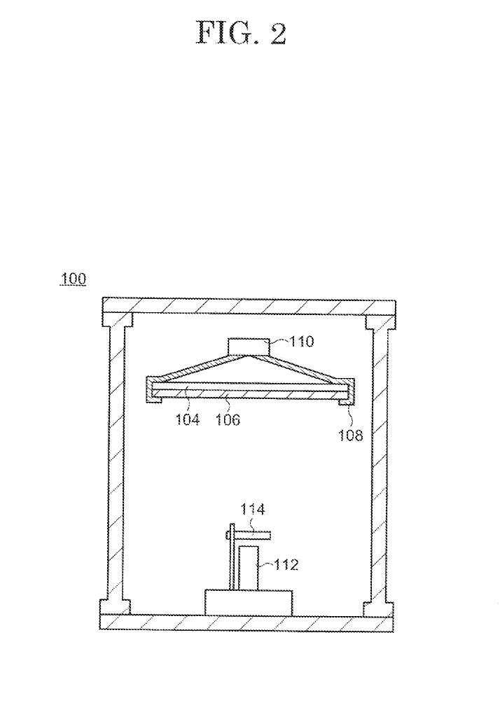

The structure of a vapor deposition device 10 according to one embodiment of the present invention is explained using FIG. 1 to FIG. 3. The vapor deposition device 10 includes a plurality of chambers having various functions. The example shown below is an example showing one vapor deposition chamber 100 among a plurality of chambers. FIG. 1 is a top surface diagram of a vapor deposition device according to one embodiment of the present invention. FIG. 2 is a side surface diagram of a vapor deposition device according to one embodiment of the present invention.

As is shown in FIG. 1, the vapor deposition chamber 100 is partitioned from an adjacent chamber by a load lock door 102. It is possible to ensure that the inside of the deposition chamber 100 is in a high vacuum reduced pressure state or a state in which an inert gas such as nitrogen or argon is filled into the chamber. Therefore, a depressurizing device or a gas suction and exhaust mechanism and the like which are not shown in the diagram are connected to the vapor deposition chamber 100.

The vapor deposition chamber 100 has a structure in which it is possible to house an object on which a vapor deposition film is formed. An example in which a plate shaped vapor deposition target substrate 104 is used as the object is explained herein. As is shown in FIG. 1 and FIG. 2, an evaporation source 112 is arranged under the vapor deposition target substrate 104. The evaporation source 112 has a substantially rectangular shape and is arranged along one side of the vapor deposition target substrate 104. This type of evaporation source 112 is called a linear source type. In the case when the linear source type evaporation source 112 is used, the vapor deposition chamber 100 has a structure in which the vapor deposition target substrate 104 and the evaporation source 112 move relatively. FIG. 1 shows an example in which the evaporation source 112 is fixed and the vapor deposition target substrate 104 moves above the evaporation source 112.

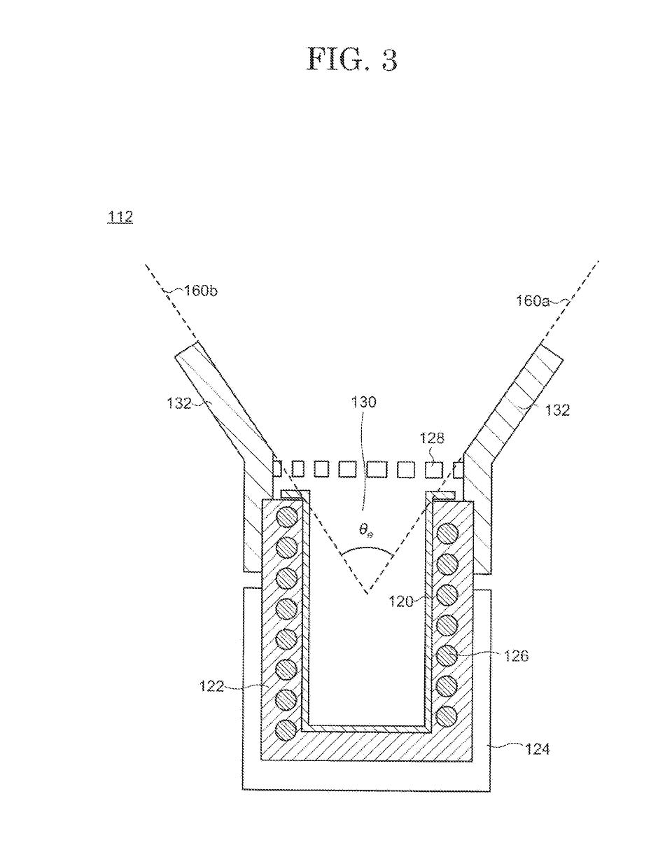

The evaporation source 112 is filled with a material to be deposited on the vapor deposition target substrate 104. The evaporation source 112 has a heating part 122 (see FIG. 3 described below) for heating the material. When the material is heated by the heating part 122 of the evaporation source 112, the heated material is vaporized to become a vapor and heads towards the vapor deposition target substrate 104 from the evaporation source 112. When the vapor of the material reaches the surface of the vapor deposition target substrate 104, the vapor is cooled and solidified, and the material is deposited on the surface of the vapor deposition target substrate 104. In this way, a thin film of the material is formed on the vapor deposition target substrate 104 (on the surface on the lower side of the vapor deposition target substrate 104 in FIG. 2).

As is shown in FIG. 2, the vapor deposition chamber 100 is further arranged with a holder 108 for holding the vapor deposition target substrate 104 and the vapor deposition mask 106, a movement mechanism 110 for moving the holder 108 and a shutter 114. The positional relationship between the vapor deposition target substrate 104 and the vapor deposition mask 106 is maintained by the holder 108. The vapor deposition target substrate 104 and the vapor deposition mask 106 are moved above the evaporation source 112 by the movement mechanism 110. The shutter 114 is arranged so as be able to move above the evaporation source 112. Since the shutter 114 moves above the evaporation source 112, the shutter 114 blocks vapor of the material which is heated by the evaporation source 112. Since the shutter 114 moves to a position where it does not overlap with the evaporation source 112, vapor of the material can reach the vapor deposition target substrate 104 without being blocked by the shutter 114. Opening and closing of the shutter 114 is controlled by a control device which is not shown in the diagram.

Although a linear source type evaporation source 112 is shown in the example shown in FIG. 1, the evaporation source 112 is not limited to the shape described above and can have any shape. For example, the shape of the evaporation source 112 may be a so-called point source type in which the material used for vapor deposition is selectively arranged at the center of gravity of the vapor deposition target substrate 104 the vicinity thereof. In the case of the point source type, the relative position between the vapor deposition target substrate 104 and the evaporation source 112 may be fixed, and a mechanism for rotating the vapor deposition target substrate 104 may be arranged in the vapor deposition chamber 100.

FIG. 3 is a cross sectional diagram of an evaporation source according to one embodiment of the present invention. The evaporation source 112 includes a storage container 120, a heating part 122, a vapor deposition holder 124, a mesh shaped metal plate 128 and a pair of guide plates 132.

The storage container 120 is a member for holding a material to be deposited. For example, a member such as a crucible can be used as the storage container 120. The storage container 120 is detachably held inside the heating part 122. The storage container 120 may contain a metal such as tungsten, tantalum, molybdenum, titanium or nickel or an alloy thereof. Alternatively, the storage container 120 may include an inorganic insulator such as alumina, boron nitride or zirconium oxide and the like.

The heating part 122 is detachably held inside the vapor deposition holder 124. The heating part 122 has a structure for heating the storage container 120 using a resistance heating system. Specifically, the heating part 122 has a heater 126. By making the heater 126 conductive, the heating part 122 is heated and the material in the storage container 120 is heated and vaporized. The vaporized material is output to the outside of the storage container 120 from an opening 130 of the storage container 120. The mesh shaped metal plate 128 which is arranged to cover the opening 130 suppresses the bumped material from being discharged to the outside of the storage container 120. The heating part 122 and the vapor deposition holder 124 may include the same material as the storage container 120.

The pair of guide plates 132 is arranged on the upper part of the evaporation source 112. At least a part of the guide plate 132 is inclined with respect to the side surface or the vertical direction of the storage container 120. The angle at which the vapor of the material spread (referred the injection angle herein) is controlled by the inclination of the guide plate 132 so that it is possible to provide directionality of the vapor in the flight direction. The injection angle is determined by an angle θe (in degree units) formed by the two guide plates 132. The angle θe is appropriately adjusted according to the size of the vapor deposition target substrate 104 and the distance between the evaporation source 112 and the vapor deposition target substrate 104. The angle θe is, for example, 40° or more and 80° or less, 50° or more and 70° or less, and typically 60°. The surfaces formed by the inclined surfaces of the guide plate 132 are critical surfaces 160a and 160b. The vapor of the material flies through a space sandwiched between the critical surfaces 160a and 160b. Although not shown in the diagram, in the case when the evaporation source 112 is a point source, the guide plate 132 may be a part of a cone shaped surface.

It is possible to select the material to be vapor deposited from various materials and can be either an organic compound or an inorganic compound. For example, a light emitting material or an organic compound having a carrier transport property can be used as the organic compound. A metal, an alloy thereof or a metal oxide and the like can be used as the inorganic compound. A single storage container 120 may be filled with a plurality of materials to form a film. Although not shown in the diagram, the vapor deposition chamber 100 may be structured so that a plurality of evaporation sources is used and different materials can be heated at the same time.

[Structure of Vapor Deposition Mask 106]

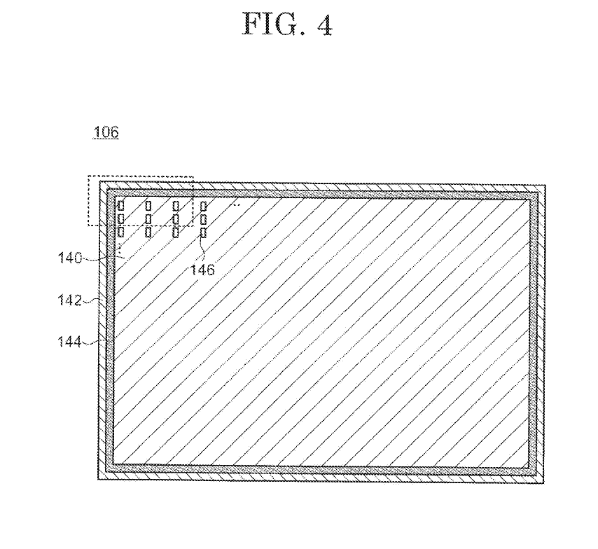

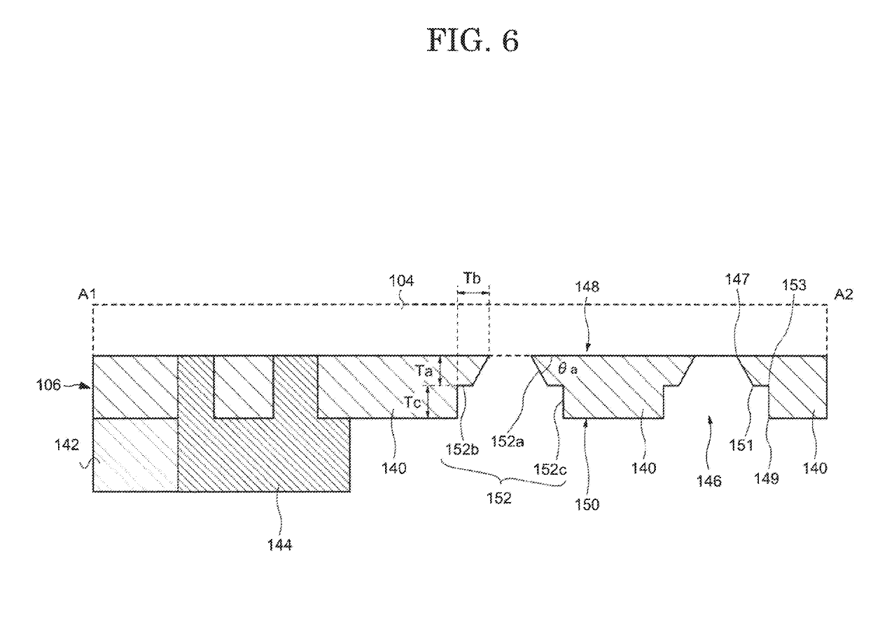

The structure of the vapor deposition mask 106 according to one embodiment of the present invention is explained using FIG. 4 to FIG. 6. FIG. 4 is a top surface diagram of a vapor deposition mask according to one embodiment of the present invention. The vapor deposition mask 106 includes a metal plate 140, a frame 142 and a connecting part 144. In the explanation below, the vapor deposition mask 106 is explained assuming that the vapor deposition mask 106 is in a state where it is placed under the vapor deposition target substrate 104. Since the vapor deposition target substrate 104 is not a member which forms the vapor deposition mask 106, it is shown by a dotted line (see FIG. 6).

The metal plate 140 is arranged with a plurality of openings 146 which passes through the metal plate 140. A region other than the opening 146 of the metal plate 140 is called a non-opening part. The non-opening part surrounds each opening 146. The frame 142 is arranged along the outer periphery of the metal plate 140 on the outer side of the region arranged with the plurality of openings 146. The connecting part 144 surrounds the plurality of openings 146 and contacts the metal plate 140 and the frame 142 so as to connect them to each other.

At the time of vapor deposition, the vapor deposition mask 106 and the vapor deposition target substrate 104 are aligned so that the vapor deposition region of the vapor the deposition target substrate 104 to be vapor deposited and the opening 146 overlap, and the non-deposition region of the vapor deposition target substrate 104 and the non-opening part overlap each other. Vapor of a material vapor passes through the opening 146 and material is deposited in the vapor deposition region of the vapor deposition target substrate 104.

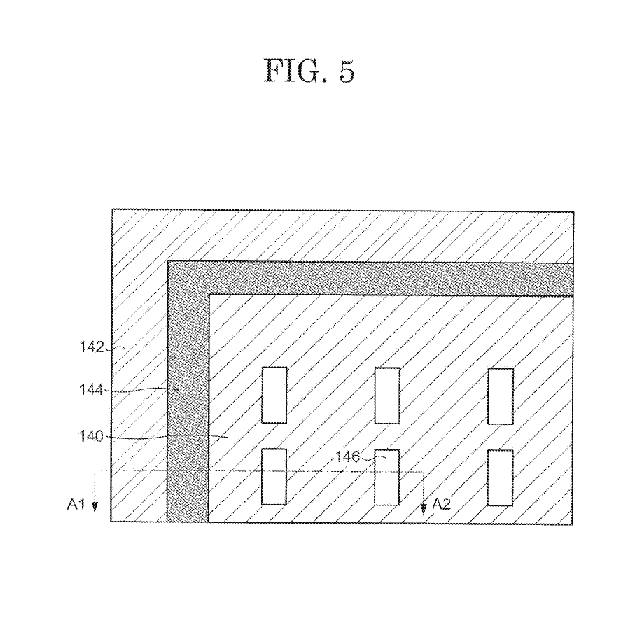

An enlarged diagram of a region surrounded by a dotted line in FIG. 4 is shown in FIG. 5. As is shown in FIG. 5, in the case when the vapor deposition regions of the vapor deposition target substrate 104 are matrix shaped, the openings 146 of the vapor deposition mask 106 are also arranged in a matrix shape. However, the arrangement of the openings 146 is not necessarily limited to the matrix shape shown in FIG. 4 and FIG. 5, and are appropriately adjusted according to the position of the vapor deposition region.

The metal plate 140 and the connecting part 144 contain a zero-valent metal such as nickel, copper, titanium and chromium. For example, the metal plate 140 and the connecting part 144 are preferred to include nickel. The composition of the materials of the metal plate 140 and the connection part 144 may be the same or different. The frame 142 also contains the zero valent metals described above and are selected from nickel, iron, cobalt, chromium and manganese or the like. For example, the frame 142 may be an alloy including iron and chromium, an alloy including iron, nickel, and manganese, and an alloy including carbon.

A cross sectional diagram taken along a dotted line A1-A2 in FIG. 5 is shown in FIG. 6. FIG. 6 shows a state in which the vapor deposition mask 106 is arranged below the vapor deposition target substrate 104. In this case, vapor the deposition mask 106 is arranged between the vapor deposition target substrate 104 and the evaporation source 112 (see FIG. 2). Here, among opposing main surfaces (upper surface and lower surface) of the vapor deposition mask 106, the main surface which is arranged at a position close to the vapor deposition target substrate 104 during vapor deposition is defined as an upper surface (or the first surface) 148, and a main surface which is arranged at a position far from the vapor deposition target substrate 104 is defined as a lower surface (or a second surface) 150. Also, in the connecting part 144, the main surface which is arranged at a position close to the vapor deposition target substrate 104 during vapor deposition is defined as an upper surface (or the first surface), and the main surface which is arranged at a position far from the vapor deposition target substrate 104 is defined as a lower surface (or the second surface). The upper surface 148 of the vapor deposition mask 106 and the upper surface of the connecting part 144 are located on the same plane.

When one opening 146 is focused on, the opening 146 is a through hole which passes from the upper surface 148 to the lower surface 150. The side wall of the opening 146 is divided into a first side wall 152a, a second side wall 152b and a third side wall 152c from the upper surface 148 side toward the lower surface 150 side. The first side wall 152a is inclined at an angle θa with respect to the upper surface 148. The second side wall 152b is largely parallel to the upper surface 148 and the lower surface 150. The third side wall 152c is approximately orthogonal with respect to the upper surface 148 and the lower surface 150. In other words, the angle formed by the second side wall 152b and the third side wall 152c is approximately 90°. In order to reduce variation in the size of the opening 146 in the manufacturing process of the vapor deposition mask 106 described herein, it is preferred that the angle formed by the vapor deposition mask 106 is 85° or more and 90° or less. As described above, when the upper surface 148 is placed on a horizontal surface, the angle of the second side wall 152b with respect to the horizontal direction is smaller than the angle θa of the first side wall 152a with respect to the horizontal direction, and the angle of the third side wall 152c with respect to the horizontal direction is larger than the angle θa of the first side wall 152a. Furthermore, θa is 60° or more and less than 90°, preferably 70° or more and 80° or less.

Rephrasing the structure described above, the first side wall 152a is a side wall between the first opening end 147 on the upper surface 148 side of the opening 146 and a first point 151. The second side wall 152b is a side wall between the first point 151 and a second point 153. The third side wall 152c is a side wall between the second point 153 and the second opening end 149 on the lower surface 150 side of the opening 146. Here, in a planar view, the second point 153 is located further to the outside than the first point 151.

The vapor deposition mask 106 shown in FIG. 6 is formed using one layer. That is, the vapor deposition mask 106 is a single-piece member which is continuous from the upper surface 148 to the lower surface 150. However, the vapor deposition mask 106 may also be formed of two or more layers, and may not be the single-piece member which continuous from the upper surface 148 to the lower surface 150.

The height of the first side wall 152a and the third side wall 152c can be arbitrarily adjusted. In other words, the height Ta of the first side wall 152a from the upper surface 148 to the second side wall 152b in a vertical direction when the upper surface 148 is placed on a horizontal surface may be the same or different as the height Tc of the third side wall 152c from the second side wall 152b to the lower surface 150. In the latter case, the height Ta may be smaller or larger than the height Tc. The height Ta is 1 μm or more and 10 μm or less, preferably 1.5 μm or more and 5 μm or less, and more preferably 2 μm or more and 3 μm or less. The height Tc is 2 μm or more and 15 μm or less, preferably 5 μm or more and 10 μm or less.

The width Tb in the horizontal direction from the first opening end 147 to the second point 153 can also be arbitrarily adjusted. The width Tb is 1 μm or more and 5 μm or less, preferably 2 μm or more and 4 μm or less.

In a planar view, in the case when the second open end 149 exists further inside than the position where the extension line of the first side wall 152a and the same plane of the lower surface 150 or the lower surface 150 intersect, a part of the vapor flying from an oblique direction to the vapor deposition target substrate 104 exposed by the opening 146 is blocked by the second opening end 149. Therefore, in a planar view, it is preferred that the second opening end 149 exists at the same position or further outside than the position where the extension line of the first side wall 152a intersects the same plane of the lower surface 150 or the lower surface 150.

For example, when θa is about 75° , design should be performed so that the conditions below are satisfied.

In the case when the width Tb is about 2 μm

the height Ta is about 2 μm, and the height Tc is about 5.5 μm.

In the case when the width Tb is about 3 μm

the height Tc is 9 μm or less in the case when the height Ta is about 2 μm, and the height Tc is 8 μm or less in the case when the height Ta is about 3 μm.

In the case when the width Tb is about 4 μm

the height Tc is 12 μm or less in the case when the height Ta is about 2 μm, and the height Tc is 11 μm or less in the case when the height Ta is about 3 μm.

The material which is stored in the storage container 120 is heated and vaporized by the heater 126. After the vapor obtained by vaporization passes through the opening 146 of the vapor deposition mask 106, it reaches the vapor deposition target substrate 104 where it solidifies and is deposited. In this way, a thin film of the material can be selectively formed in the vapor deposition region.

In the embodiment described above, although an example of the structure in which the second side wall 152b is largely horizontal and the third side wall 152c is largely vertical was illustrated, the structure is not limited to this. As is described later, the second side wall 152b may also be inclined at a limited angle with respect to the horizontal direction, and the third side wall 152c may form an acute angle (that is, an angle smaller than the vertical) with respect to the horizontal direction.

[Manufacturing Method of Vapor Deposition Mask 106]

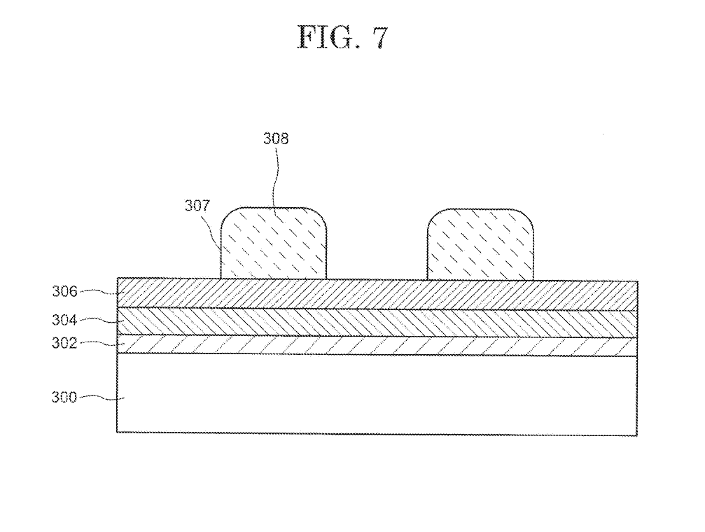

A method of manufacturing the vapor deposition mask 106 according to one embodiment of the present invention is explained using FIG. 7 to FIG. 12. FIG. 7 to FIG. 12 are cross-sectional diagrams showing a method of manufacturing a vapor deposition mask according to one embodiment of the present invention,

As is shown in FIG. 7, a peeling layer 302, a conductive layer 304 and a metal layer 306 (first film) are formed in this sequence on a substrate 300 having rigidity (also called a base substrate), and a resist mask 308 is formed there upon. In the present embodiment, the resist mask 308 is in contact with the metal layer 306.

A substrate having rigidity such as a glass substrate, a stainless steel substrate, a silicon substrate or a quartz substrate and the like is used as the substrate 300. For example, the thickness of the substrate 300 is 300 μm or more and 3 mm or less, preferably 500 μm or more and 2 mm or less.

The peeling layer 302 is a layer for separating the substrate 300 from the conductive layer 304 and the metal layer 306 in a later process. A resin layer such as a polyimide resin, an acrylic resin, an epoxy resin, a silicone resin, a fluororesin or a siloxane resin is used as the peeling layer 302. In the case when a resin layer is used as the peeling layer 302, the substrate 300 can be separated from the conductive layer 304 and the metal layer 306, for example, by irradiating the peeling layer 302 with laser light. An inorganic layer such as a metal layer, a metal oxide layer or an inorganic insulating layer may also be used in addition to a resin layer as the peeling layer 302.

The conductive layer 304 is a layer that functions as a seed layer when the vapor deposition mask 106 is formed by an electroform plating method in a later process. However, the conductive layer 304 can be omitted in the case where the vapor deposition mask 106 is formed by a method other than the electroform plating method. The conductive layer 304 is formed of, for example, a known material which functions as a seed layer in the electroform plating method. These materials may be used as a single layer or in stacked layers as the conductive layer 304. Alternatively, an alloy selected from these materials may be used as the conductive layer 304. The thickness of the conductive layer 304 can be appropriately adjusted within a range of 1 μm or more and 10 μm or less. Furthermore, the conductive layer 304 may also function as an etching stopper in a later process (an etching process of the metal layer 306). Therefore, the etching rate of the material which is present on the surface of the conductive layer 304 is lower than the etching rate of the metal layer 306 described herein.

The metal layer 306 (first film) is etched in a later process and a pattern for forming the first sidewall 152a of the vapor deposition mask 106 is provided. Materials such as titanium, aluminum, tungsten, tantalum, and molybdenum are used as the metal layer 306. These materials may be used as a single layer or in stacked layers as the metal layer 306. Alternatively, an alloy selected from these materials may be used as the metal layer 306. The thickness of the metal layer 306 can be appropriately adjusted within a range of, for example, 2 μm or more and 5 μm or less. The height Ta of the first side wall 152a of the vapor deposition mask 106 is determined according to the thickness of the metal layer 306. In the present embodiment, a structure of titanium/aluminum/titanium is used as the metal layer 306. An insulating layer such as silicon nitride may also be used instead of the metal layer 306.

The resist mask 308 (mask member) is a mask for etching the metal layer 306. Furthermore, the resist mask 308 provides a pattern for forming the third side wall 152c of the vapor deposition mask 106. The resist mask 308 is formed at a position where the opening 146 is arranged in the vapor deposition mask 106. In the present embodiment, a side wall 307 of the resist mask 308 is vertical. The shape of the side wall 307 determines the shape of the third side wall 152c. A negative type or a positive type photoresist is used as the resist mask 308. In this embodiment, a negative photoresist is used. This is because the negative type photoresist tends to have a more stable shape even when over-exposed, that is, the exposure and development margins tend to be wider than the positive type photoresist. It is possible to appropriately adjust the thickness of the resist mask 308 within a range of 5 μm or more and 20 μm or less. The thickness of the resist mask 308 is required to be larger than the height Tc of the third side wall 152c.

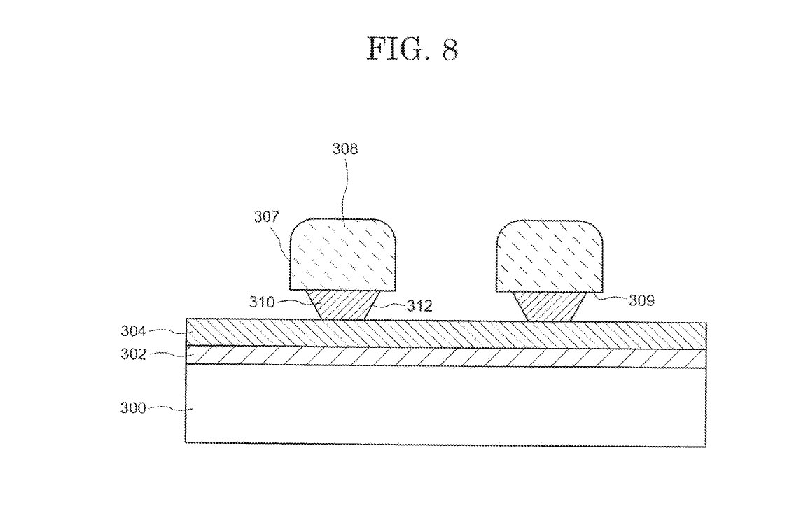

As is shown in FIG. 8, the metal layer 306 is etched using the resist mask 308 as a mask to form a first sidewall formation pattern 310 (first pattern). This etching is performed by dry etching. Isotropic dry etching conditions are adopted for this dry etching. That is, the dry etching conditions are conditions for not only etching the metal layer 306 in its film thickness direction but also side etching in a horizontal direction. That is, the lower surface 309 of the resist mask 308 on the side of the substrate 300 is exposed by this dry etching. In the first sidewall formation pattern 310, the sidewall 312 forms an obtuse angle with respect to the horizontal direction. That is, the first sidewall formation pattern 310 has a reverse taper shaped pattern. When the metal layer 306 is etched using isotropic dry etching conditions, horizontal etching proceeds as it gets further away from the resist mask 308, and the first side wall formation pattern 310 takes on an inverse taper shaped pattern as is shown in FIG. 8. In order to form the first sidewall formation pattern 310 into an inverse taper shaped pattern, it is desirable to adopt dry etching conditions for example which promote chemical reactive etching by radicals and, reversely, conditions with a small amount of ion assisted etching.

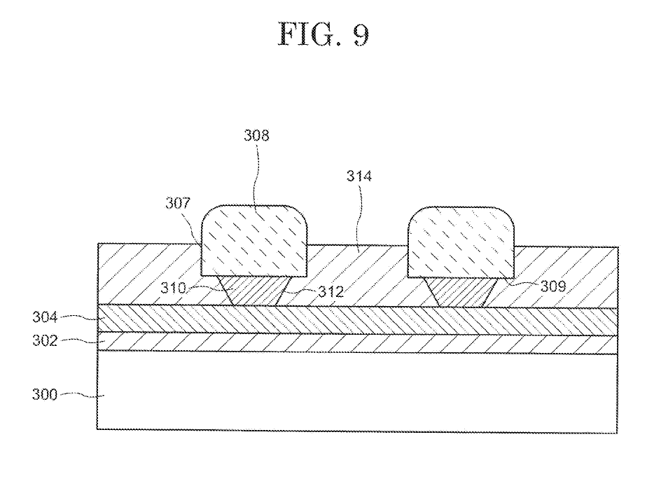

As is shown in FIG. 9, a vapor deposition mask member 314 is formed in contact with the side wall 312 of the first side wall formation pattern 310, the side wall 307 of the resist mask 308, and the lower surface 309 of the resist mask 308. The vapor deposition mask member 314 is formed by an electroform plating method. That is, the vapor deposition mask member 314 is formed by a plating method in which a current is supplied to the conductive layer 304. Although the manufacturing method is exemplified in FIG. 9 in which the vapor deposition mask member 314 is formed to a height at the middle of the side wall 307 of the resist mask 308, the manufacturing method is not limited to this. For example, the vapor deposition mask member 314 may be formed higher than the resist mask 308 and polished or ground to a desired height.

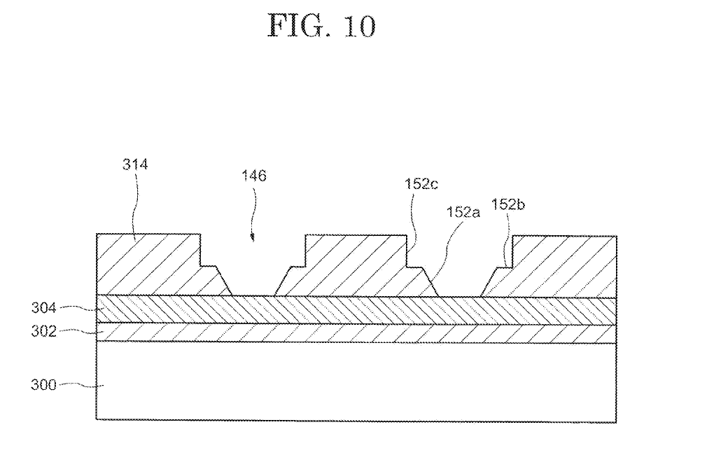

As is shown in FIG. 10, by removing the resist mask 308 and the first sidewall formation pattern 310, the vapor deposition mask member 314 is formed arranged with the opening 146. The first side wall 152a is formed at a position corresponding to the side wall 312 of the first side wall formation pattern 310. The second side wall 152b is formed at a position corresponding to the lower surface 309 of the resist mask 308. The third side wall 152c is formed at a position corresponding to the side wall 307 of the resist mask 308. That is, the shapes of the first side wall 152a to the third side wall 152c are controlled by the shapes of the resist mask 308 and the first side wall formation pattern 310.

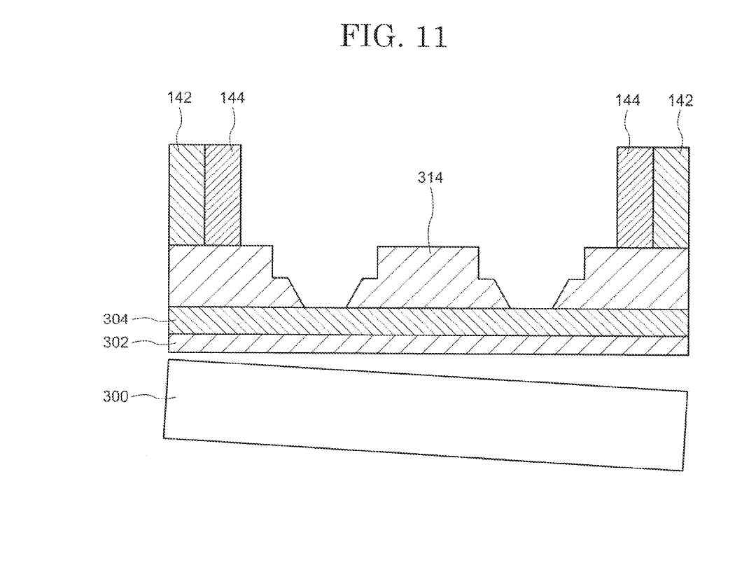

As is shown in FIG. 11, the frame 142 is joined to the periphery part of the vapor deposition mask member 314, and the connecting part 144 is formed by the electroform plating method. Next, the substrate 300 is peeled from the peeling layer 302.

Joining of the frame 142 is performed using a resin adhesive layer or a metal adhesive layer for example. In the case where joining is performed using a metal adhesive layer, it is preferred to use a metal containing a relatively low melting point metal such as zinc or tin or an alloy thereof and a metal joining layer containing several percent (for example, 3 percent or more and 10 percent or less, or 5 percent or more and 8 percent or less) of phosphorus can be used. It is possible to join the vapor deposition mask member 314 and the frame 142 by pressurizing them while heating interposed by the metal adhesion layer. Electroform plating is performed in a state where a resist mask is formed in a region other than where the connecting part 144 is formed. Joining of the frame 142 is not limited to the method described above.

In the case when a glass substrate or a quartz substrate is used as the substrate 300, peeling of the substrate 300 is performed by irradiating the substrate 300 with laser light from below the substrate 300 for example. When laser light is irradiated from below the substrate 300, the laser light passes through the substrate 300 and is absorbed by the peeling layer 302. The peeling layer 302 generates heat by the laser light, and the substrate 300 is peeled from the peeling layer 302 by thermal energy thereof.

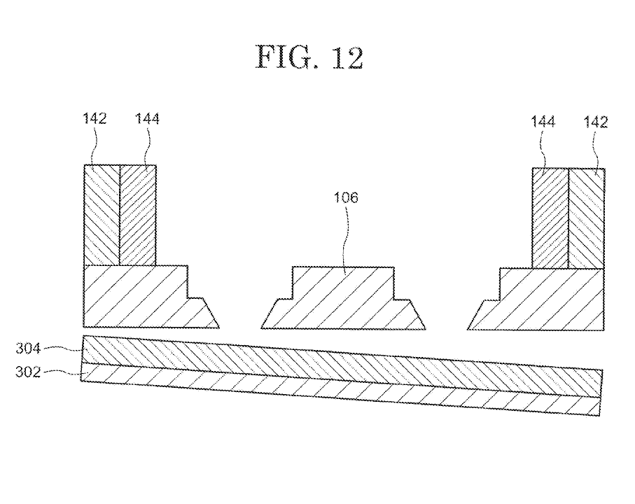

As is shown in FIG. 12, the peeling layer 302 and the conductive layer 304 are peeled off from the vapor deposition mask member 314 and the vapor deposition mask 106 is obtained. Peeling of the peeling layer 302 and the conductive layer 304 may be performed by physical external force or by a heat treatment. The peeling layer 302 and the conductive layer 304 may be removed by etching or the like instead of peeling.

Since the vapor deposition mask 106 (vapor deposition mask member 314) is thin and has a low rigidity compared to the substrate 300, the vapor deposition mask 106 may be damaged by a peeling impact when the substrate 300 is peeled from the vapor deposition mask 106. However, by forming the vapor deposition mask 106 by a two-stage peeling process as described above, it is possible to suppress damage to the vapor deposition mask 106.

As was described above, by forming the first sidewall formation pattern 310 by dry etching, it is possible to form a fine first sidewall formation pattern 310 with high accuracy. Together with this, it is possible to accurately realize a fine opening pattern 146 of the vapor deposition mask 106. In addition, it is possible to form the vapor deposition mask 106 with one layer by performing electroforming plating using the resist mask 308 and the first sidewall formation pattern 310 as a mold.

Although the manufacturing method in which the vapor deposition mask member 314 is formed by the electroform plating method was explained in the present embodiment, the formation of the vapor deposition mask member 314 is not limited to the electroform plating method. For example, a material which serves as the vapor deposition mask member 314 may be formed by a coating method on the structure in the state shown in FIG. 8. In order to easily peel off the peeling layer 302 and the conductive layer 304 from the vapor deposition mask member 314, a process for reducing adhesion of the conductive layer 304 and the vapor deposition mask member 314 to the surface of the conductive layer 304 may be performed before the vapor deposition mask member 314 is formed. Specifically, a thin hydroxide layer may be formed to an extent that allows a current to flow on the surface of the conductive layer 304.

### Second Embodiment

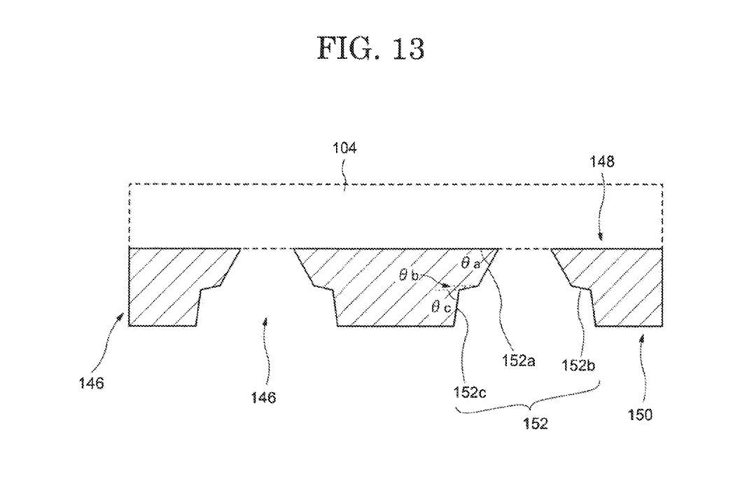

A vapor deposition mask and a manufacturing method thereof according to one embodiment of the present invention is explained using FIG. 13 to FIG. 15. The vapor deposition mask 106 according to the second embodiment has the opening 146 with a different shape compared with the vapor deposition mask 106 according to the first embodiment. The difference of the vapor deposition mask 106 of the second embodiment from the first embodiment is explained.

[Structure of Vapor Deposition Mask 106]

FIG. 13 is a cross-sectional diagram of a vapor deposition mask according to one embodiment of the present invention. As is shown in FIG. 13, when the upper surface 148 of the vapor deposition mask 106 is placed on a horizontal surface, the second side wall 152b is not horizontal but is inclined at an angle θb with respect to the horizontal direction. In addition, the third side wall 152c is not vertical but is inclined at an angle θc with respect to the horizontal direction. Here, the angle θb is smaller than the angle θa, and the angle θc is larger than the angle θa. Each of the angles θa, θb, and θc have a forward taper shape.

[Manufacturing Method of Vapor Deposition Mask 106]

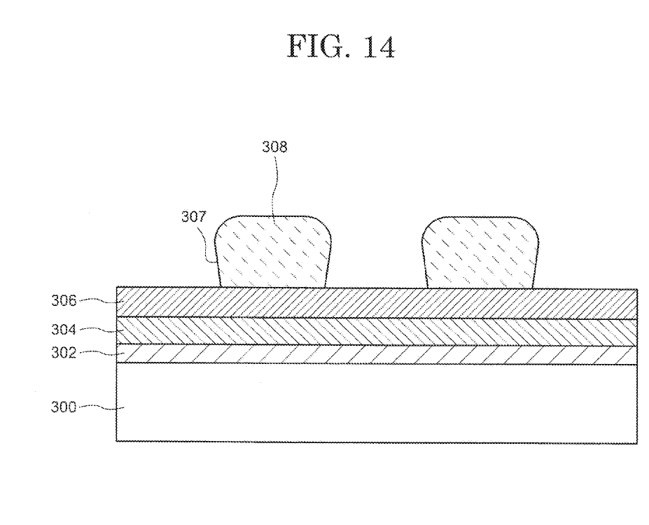

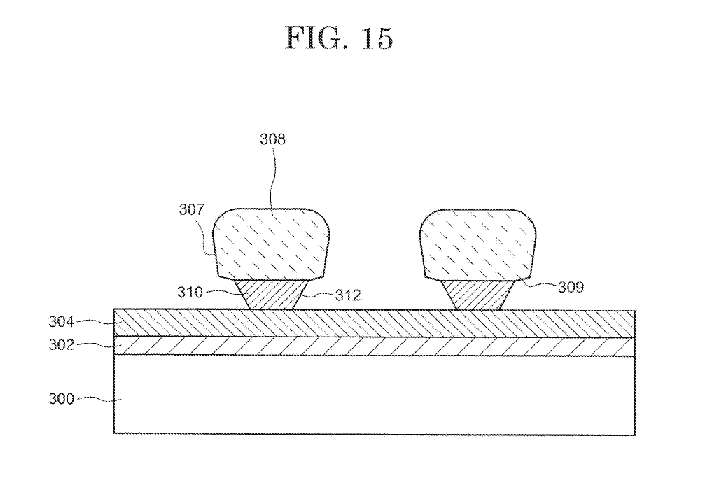

FIG. 14 and FIG. 15 are cross-sectional diagrams showing a method of manufacturing a vapor deposition mask according to one embodiment of the present invention. The processes in FIG. 14 and FIG. 15 correspond to the processes in FIG. 7 and FIG. 8 in the first embodiment respectively.

As is shown in FIG. 14, the side wall 307 of the resist mask 308 is not vertical but is inclined at an obtuse angle with respect to the horizontal direction. That is, the resist mask 308 of the present embodiment has an inverted taper shape. The shape of the resist mask 308 can be adjusted by the exposure conditions for forming the pattern of the resist mask 308.

As is shown in FIG. 15, the metal layer 306 is etched using the resist mask 308 as a mask and the first sidewall formation pattern 310 is formed. By adjusting the dry etching conditions and performing etching under conditions of high isotropy during this etching, the metal layer 306 is side-etched while etching the lower surface 309 of the resist mask 308. By performing this etching, the lower surface 309 takes on an inclined shape with respect to the horizontal direction.

By forming the vapor deposition mask member 314 and removing the resist mask 308 and the first side wall formation pattern 310 as is shown in FIG. 9 to FIG. 12 with respect to the structure shown in FIG. 15, it is possible to form the vapor deposition mask 106 shown in FIG. 13.

### Third Embodiment

In the present embodiment, a manufacturing method of a display device 200 applied with the thin film forming method using the vapor deposition mask 106 explained in the first and second embodiments is explained. A method of manufacturing an organic EL display device in which a plurality of pixels each having an organic light emitting element (referred to below as a light emitting element) is formed over an insulating substrate 202 is explained as the display device 200 according to the third embodiment. Furthermore, the details described in the first and second embodiments may be omitted.

[Structure of Array Substrate]

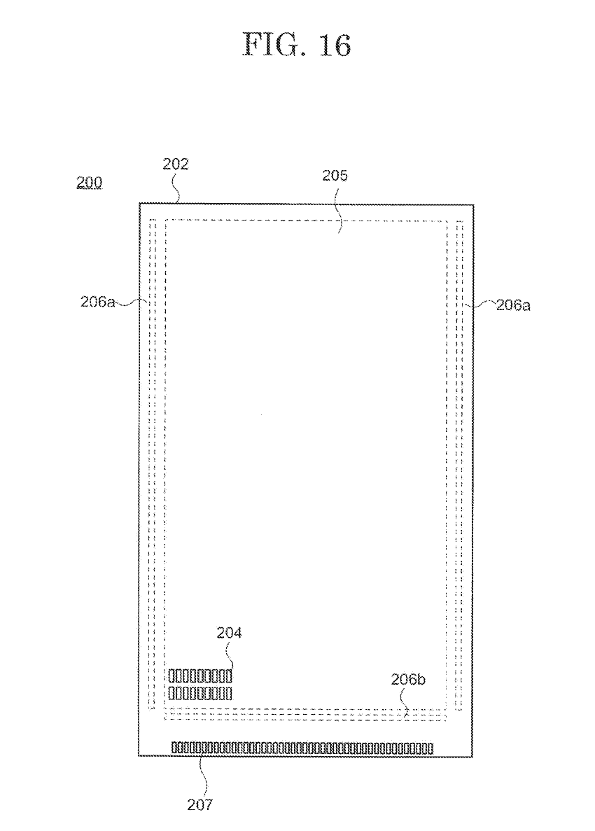

FIG. 16 is a top surface diagram a display device according to one embodiment of the present invention. The display device 200 has an insulating substrate 202. A plurality of pixels 204 and a drive circuit 206 (gate side drive circuit 206a, source side drive circuit 206b) for driving the plurality of pixels 204 are arranged above the insulating substrate 202. The insulating substrate 202 is a glass substrate or a resin substrate for example. The plurality of pixels 204 is periodically arranged, and a display region 205 is defined by the plurality of pixels 204. As is described below, a light emitting element 260 is arranged in each of the plurality of pixels 204.

The drive circuit 206 is arranged in a periphery region around the display region 205. Various wirings (not shown in the diagram) which are formed by a patterned conductive film extend from the display region 205 and the drive circuit 206 to one side of the insulating substrate 202. These wirings are exposed on a surface in the vicinity of an end part of the insulating substrate 202 to form a terminal 207. These terminals 207 are electrically connected to a flexible printed circuit board (FPC) which is not shown in the diagram. Various signals for driving the display device 200 are input to the drive circuit 206 and each of the plurality of pixels 204 via the terminal 207. Although not shown in the diagram, a drive IC including an integrated circuit may be further mounted in addition to or instead of the drive circuit 206.

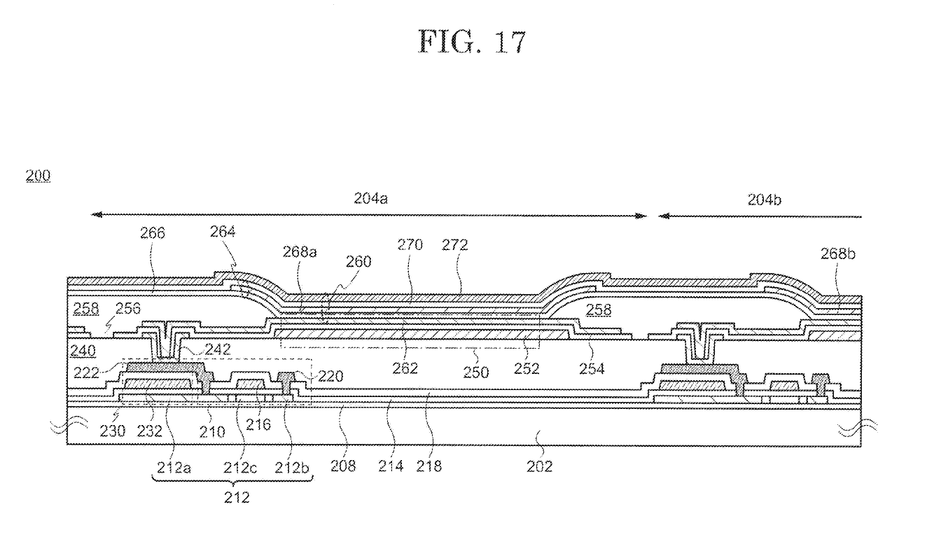

FIG. 17 is a schematic cross-sectional diagram along two adjacent pixels (a first pixel 204a and a second pixel 204b). A pixel circuit is formed in each of the first pixel 204a and the second pixel 204b. The structure of the pixel circuit is arbitrary. In FIG. 17, a drive transistor 210, a storage capacitor 230, an additional capacitor 250 and a light emitting element 260 are shown as a pixel circuit.

Each element which is included in a pixel circuit is arranged above the insulating substrate 202 via an undercoat 208. The drive transistor 210 includes a semiconductor film 212, a gate insulating film 214, a gate electrode 216, a drain electrode 220 and a source electrode 222. The gate electrode 216 is arranged to intersect at least a part of the semiconductor film 212 interposed by the gate insulating film 214. The semiconductor film 212 includes a source region 212a, a drain region 212b and a channel 212c. The channel 212c is a region where the semiconductor film 212 and the gate electrode 216 overlap. The channel 212c is arranged between the source region 212a and the drain region 212b.

A capacitor electrode 232 exists in the same layer as the gate electrode 216 and overlaps the source region 212a via the gate insulating film 214. An interlayer insulating film 218 is arranged above the gate electrode 216 and the capacitor electrode 232. Openings which reach the drain region 212b and the source region 212a are respectively formed in the interlayer insulating film 218 and the gate insulating film 214. The drain electrode 220 and the source electrode 222 are arranged on the interior of these openings. The source electrode 222 overlaps the capacitor electrode 232 via the interlayer insulating film 218. The storage capacitor 230 is formed by the source region 212a, the capacitor electrode 232, the gate insulating film 214 between the source region 212a and the capacitor electrode 232, the capacitor electrode 232, the source electrode 222, and the interlayer insulating film 218 between the capacitor electrode 232 and the source electrode 222.

A planarization film 240 is arranged above the drive transistor 210 and the storage capacitor 230. The planarization film 240 includes an opening which reaches the source electrode 222. A connection electrode 242 which covers the opening and a part of the upper surface of the planarization film 240 is arranged in contact with the source electrode 222. The additional capacitor electrode 252 is arranged above the planarization film 240. The capacitor insulating film 254 is arranged to cover the connection electrode 242 and the additional capacitor electrode 252. The capacitor insulating film 254 exposes a part of the connection electrode 242 at the opening of the planarization film 240. In this way, the pixel electrode 262 of the light emitting element 260 and the source electrode 222 are electrically connected through the connection electrode 242. The capacitor insulating film 254 is arranged with an opening 256 which allows contact between a partition wall 258 and the planarization film 240 which is arranged above. Impurities within the planarization film 240 can be removed through the opening 256, and in this way, it is possible to improve reliability of a pixel circuit and the light emitting element 260. Furthermore, formation of the connection electrode 242 and the opening 256 is optional.

A pixel electrode 262 is arranged above the capacitor insulating film 254 to cover the connection electrode 242 and the additional capacitor electrode 252. The capacitor insulating film 254 is arranged between the additional capacitor electrode 252 and the pixel electrode 262, and the additional capacitor 250 is formed by this structure. The pixel electrode 262 is shared by the additional capacitor 250 and the light emitting element 260. The partition wall 258 which covers an end part of the pixel electrode 262 is arranged above the pixel electrode 262. The structure from the insulating substrate 202 and the undercoat 208 to the partition wall 258 may also be referred to as an array substrate. Since the array substrate can be manufactured by applying known materials and known methods, an explanation thereof is omitted.

[Structure of Light Emitting Element 260]

As is shown in FIG. 17, the light emitting element 260 includes a pixel electrode 262, an EL layer 264 and an opposing electrode 272. The EL layer 264 and the opposing electrode 272 are arranged to cover the pixel electrode 262 and the partition wall 258. In the example shown in FIG. 17, the EL layer 264 includes a hole injection layer and a hole transport layer 266, a light emitting layer 268 (light emitting layers 268a and 268b), an electron injection layer and an electron transport layer 270. The hole injection layer and the hole transport layer 266, and the electron injection layer and the electron transport layer 270 are arranged in common for all pixels 204, and are shared between all the pixels 204. Similarly, the opposing electrode 272 covers a plurality of pixels 204 and is shared by a plurality of pixels 204. On the other hand, the light emitting layer 268 is arranged separately for each pixel 204.

It is possible to apply known structures and materials as the structure and material of each of the pixel electrode 262, the opposing electrode 272 and the EL layer 264. For example, the EL layer 264 may have various functional layers such as a hole blocking layer, an electron blocking layer and an exciton blocking layer in addition to the structure described above.

The structure of the EL layer 264 may be the same among all the pixels 204, and the structure between adjacent pixels 204 may also be partially different. For example, the pixel 204 may be formed so that the structure or material of the light emitting layer 268 is different between adjacent pixels 204 and the other layers have the same structure.

[Formation Method of Light Emitting Element 260]

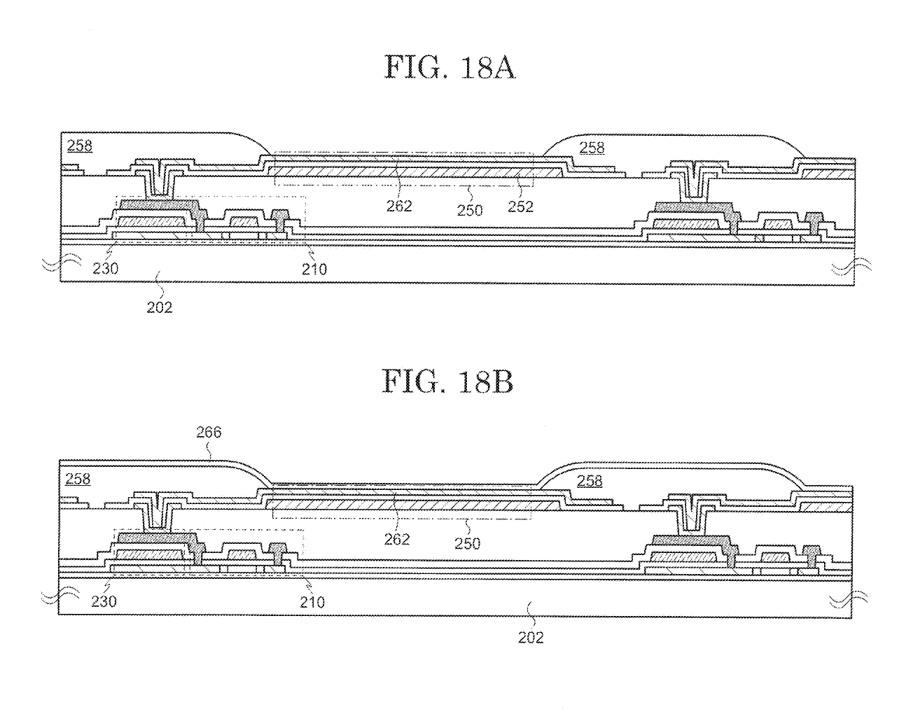

The EL layer 264 and the opposing electrode 272 can be formed using the vapor deposition mask 106 of the first and second embodiments. A method of forming the EL layer 264 and the opposing electrode 272 is explained below using FIG. 18A to FIG. 21B. In these diagrams, the EL layer 264 and the opposing electrode 272 are formed above the partition wall 258 and the pixel electrode 262. However, when the EL layer 264 and the opposing electrode 272 are vapor deposited, the evaporation source 112 is arranged under the insulating substrate 202, and the insulating substrate 202 is arranged so that the vapor deposition region faces the evaporation source 112. That is, the partition wall 258 and the pixel electrode 262 are arranged to be closer to the evaporation source 112 than the insulating substrate 202.

As is shown in FIG. 18A and FIG. 18B, a hole injection layer and a hole transport layer 266 are formed on the array substrate using a vapor deposition method. The hole injection layer and the hole transport layer 266 are shared by all the pixels 204. Therefore, the vapor deposition mask 106 which is used for vapor deposition of the hole injection layer and the hole transport layer 266 includes one opening 146 which overlaps the entire display region 205. Although the details are omitted, the vapor deposition mask 106 is arranged between the array substrate and the evaporation source 112 so that the opening 146 overlaps the display region 205, and the hole injection layer and the hole transport layer 266 are formed by vaporizing a material contained in the hole injection layer and the hole transport layer 266 in the evaporation source 112.

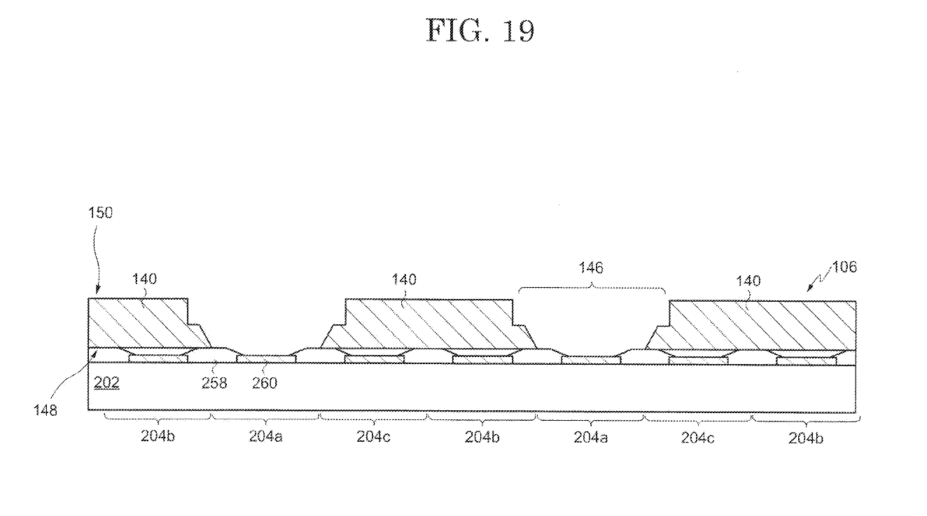

Next, the light emitting layer 268 is formed above the hole injection layer and the hole transport layer 266. In the case of performing full-color display, a plurality of pixels 204a which emits red light, pixels 204b which emit blue light, and pixels 204c which emit green light respectively are arranged in the display region 205. In the case where the pixels 204a, 204b and 204c are not particularly distinguished, they are simply called pixels 204. In the case where the pixels 204 are arranged in a matrix shape, usually the pixels 204 having different light emitting colors are periodically arranged in order. The light emitting layer 268 is formed in different processes for each light emitting color. For example, in the case of forming a pixel 204a which emits red light, as is shown in FIG. 19, the vapor deposition mask 106 is arranged so that the opening 146 of the vapor deposition mask 106 overlaps the pixel 204a and the non-opening part overlaps the pixels 204b and 204c.

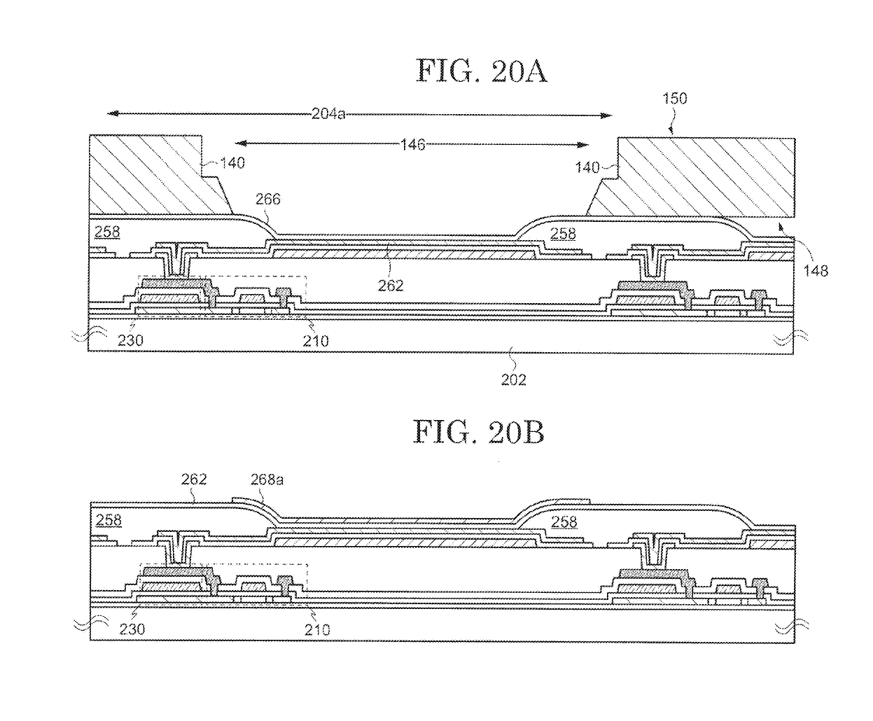

In this way, the vapor deposition mask 106 which is arranged with the opening 146 is arranged at a position where the opening 146 overlaps with the pixel 204a and the non-opening part overlaps the other pixels 204b and 204c, the upper surface 148 is arranged closer to the insulating substrate 202 (FIG. 19 and FIG. 20A) than the lower surface 150, and the material of the light emitting layer 268a of the pixel 204a is vapor deposited. In this way, the light emitting layer 268a is selectively formed above the pixel electrode 262 of the pixel 204a (FIG. 20B). Although the vapor deposition mask 106 is arranged in FIG. 20A to be in contact with the hole injection layer and the hole transport layer 266 during vapor deposition, the vapor deposition mask 106 may also be arranged to be in contact with the partition wall 258, and may also be arranged apart from the partition wall 258 and the hole injection layer and the hole transport layer 266.

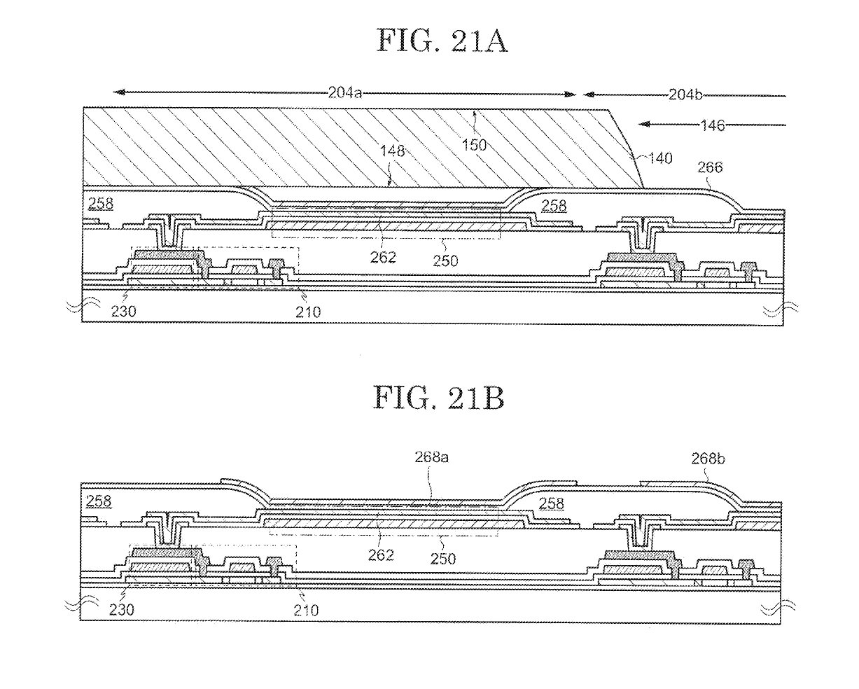

Next, a light emitting layer 268b is formed similar to the formation of the light emitting layer 268a. As is shown in FIG. 21A and FIG. 21B, the vapor deposition mask 106 is arranged so that the opening 146 overlaps the pixel 204b and the non-opening part overlaps the other pixels 204a and 204c, the upper surface 148 is arranged closer to the insulating substrate 202 (FIG. 21A) than the lower surface 150, and the material of the light emitting layer 268b of the pixel 204b is vapor deposited. In this way, the light emitting layer 268b is selectively formed above the pixel electrode 262 of the pixel 204b (FIG. 21B). The formation of the light emitting layer 268c above the pixel 204c is also performed by the same method.

Next, an electron injection layer and an electron transport layer 270 and an opposing electrode 272 are formed. Since the electron injection layer and the electron transport layer 270 and the opposing electrode 272 are shared by all the pixels 204, they can be formed using the vapor deposition mask 106 the same as vapor deposition of the hole injection layer and the hole transport layer 266. In this way, it is possible to obtain the structure shown in FIG. 17. Although not shown in the diagram, an optical adjustment layer for adjusting light from the light emitting layer 268 and a polarization plate may be arranged above the opposing electrode 272. In addition, a protective film and an opposing substrate for protecting the light emitting element 260 may be arranged above the opposing electrode 272.

As described in the first embodiment, it is possible form a fine pattern of the light emitting layer 268 with high accuracy by using the vapor deposition mask 106 according to the embodiments of the present invention. In this way, it is possible to realize a fine pixel and a high definition display device.

Each embodiment described above as embodiments of the present invention can be implemented in combination as appropriate as long as they do not contradict each other. In addition, those skilled in the art could appropriately add, delete or change the design of the constituent elements based on the display device of each embodiment, or add, omit or change conditions as long as it does not depart from the concept of the present invention and such changes are included within the scope of the present invention.

Although the case of an EL display device is mainly exemplified as a disclosure example in the present specification, the present invention can be applied to other flat panel type display devices such as self-light emitting type display devices, liquid crystal display devices or electronic paper display devices including an electrophoretic element. In addition, the size of the display device exemplified in the present specification can be applied from a medium to small size to a large size without any particular limitation.

Even if other actions and effects different from the actions and effects brought about by the aspects of each embodiment described above are obvious from the description of the present specification or those which could be easily predicted by those skilled in the art, such actions and effects are to be interpreted as being provided by the present invention.

What is claimed is:

1. A manufacturing method of a vapor deposition mask comprising: forming a first film on a substrate;
forming a mask member on the first film;
forming a first pattern by etching the first film using the mask member;
forming a vapor deposition mask member on a side surface of the first pattern and a side surface of the mask member; and
removing the first film and the mask member.

2. The manufacturing method of a vapor deposition mask according to claim 1, further comprising:
forming a conductive layer on the substrate before forming the first film; and
forming the vapor deposition mask member by a plating method by flowing a current through the conductive layer.

3. The manufacturing method of a vapor deposition mask according to claim 2, wherein the first pattern is formed by performing dry etching of the first film.

4. The manufacturing method of a vapor deposition mask according to claim 3, wherein the first pattern is formed in an inverted tapered shape by the dry etching.

5. The manufacturing method of a vapor deposition mask according to claim 4, wherein a surface of the substrate side of the mask member is exposed by the dry etching.

6. The manufacturing method of a vapor deposition mask according to claim 5, further comprising:
forming a peeling layer on the substrate before forming the conductive layer; and
peeling the peeling layer and the substrate from the vapor deposition mask member after removing the first film and the mask member.

7. The manufacturing method of a vapor deposition mask according to claim 6, wherein the peeling layer and the substrate are peeled from the vapor deposition mask member by peeling the peeling layer from the vapor deposition mask member after peeling the substrate from the peeling layer.

8. The manufacturing method of a vapor deposition mask according to claim 7, wherein an etching rate of the dry etching of the conductive layer is smaller than an etching rate of the dry etching of the first film.

9. The manufacturing method of a vapor deposition mask according to claim 6, wherein the peeling layer is a resin layer.

10. The manufacturing method of a vapor deposition mask according to claim 2, wherein the first film includes a metal.

11. The manufacturing method of a vapor deposition mask according to claim 10, wherein the first film includes any one of titanium, aluminum, tungsten, tantalum and molybdenum.

12. A vapor deposition mask comprising:
a first surface;
a second surface on an opposite side to the first surface; and
an opening passing through from the first surface to the second surface;
wherein
a side wall of the opening is separated into a first side wall, a second side wall and a third side wall from the first surface toward the second surface; and
an angle of the second side wall with respect to a horizontal direction is smaller than an angle of the first side wall with respect to a horizontal direction, and an angle of the third side wall with respect to a horizontal direction is larger than an angle of the first side wall with respect to a horizontal direction, on the condition that the first surface is placed on a horizontal surface.

13. A vapor deposition mask comprising:
a first surface;
a second surface on an opposite side to the first surface; and
an opening passing through from the first surface to the second surface;
wherein
a side wall of the opening includes a first side wall and a second side wall;
the first side wall is a side wall between a first opening end on the first surface side of the opening and a first point, and forms a first angle with respect to a horizontal direction; and
the second side wall is a side wall between a second point further to the outer side than the first point in a planar view and a second opening end on the second surface side of the opening, and forms a second angle with respect to a horizontal direction, the second angle being larger than the first angle.

14. The vapor deposition mask according to claim 12, wherein the vapor deposition mask is a single-piece member, the vapor deposition mask being continuous from the first surface to the second surface.

15. The vapor deposition mask according to claim 13, wherein the vapor deposition mask is a single-piece member, the vapor deposition mask being continuous from the first surface to the second surface.

16. The vapor deposition mask according to claim 12, wherein the vapor deposition mask is formed by a single-layer from the first surface to the second surface.

17. The vapor deposition mask according to claim 13, wherein the vapor deposition mask is formed by a single-layer from the first surface to the second surface.

18. The vapor deposition mask according to claim 12, wherein the second side wall is approximately horizontal.
